(19) United States
(12) Patent Application Publication
(10) Pub. No.: US 2024/0199377 A1
(43) Pub. Date: Jun. 20, 2024

(54) TOWER LIFT

(71) Applicant: SEMES CO., LTD., Cheonan-si (KR)

(72) Inventors: Nahyun Lee, Ansan-si (KR); Chuljun Park, Seoul-si (KR); Myungjin Lee, Hwaseong-si (KR)

(73) Assignee: SEMES CO., LTD., Cheonan-si (KR)

(21) Appl. No.: 18/542,667

(22) Filed: Dec. 16, 2023

(30) Foreign Application Priority Data
Dec. 20, 2022 (KR) 10-2022-0179790

(51) Int. Cl. B66B 5/22; B66B 7/04

(52) U.S. Cl. CPC B66B 5/22; B66B 7/044

(57) ABSTRACT

Provided is a tower lift including a rail module extending in a vertical direction, a carriage module that is movable in a magnetic levitation manner along the rail module, and a braking device configured to move integrally with the carriage module along the rail module, wherein the braking device includes a first braking body configured to prevent the carriage module from falling through selective contact with the rail module, an elastic member provided above the first braking body and configured to apply an upward elastic force to the first braking body, and an actuator provided below the first braking body and configured to pull the first braking body downward through a rotation shaft connection structure connected to the first braking body.

### CROSS-REFERENCE TO RELATED APPLICATION

This application is based on and claims priority under 35 U.S.C. § 119 to Korean Patent Application No. 10-2022-0179790, filed on Dec. 20, 2022, in the Korean Intellectual Property Office, the disclosure of which is incorporated by reference herein in its entirety.

### BACKGROUND

### 1. Field

The inventive concept relates to a tower lift comprising a braking unit.

### 2. Description of the Related Art

Typically, a manufacturing line in a semiconductor or display manufacturing plant consists of multiple floors. Equipment for performing processes such as deposition, exposure, etching, ion implantation, and cleaning may be placed on each floor of the semiconductor manufacturing line. The equipment placed on each floor may repeatedly perform a series of unit processes on a semiconductor wafer used as a semiconductor substrate or a glass substrate used as a display substrate.

A tower lift installed in a vertical direction may transport articles through each floor of the semiconductor manufacturing line, i.e., transport articles, such as semiconductor wafers or glass substrates.

A typical tower lift has a carriage module for transporting articles and a rail module for guiding the carriage module in the vertical direction. A drive belt, such as a timing belt, for elevating the carriage module is installed in the rail module. The timing belt is coupled to the carriage module and moves the carriage module in up and down directions. However, when the timing belt is driven in such a typical tower lift, particles may be generated. For example, the timing belt may rub against a pulley during operation and particles may be generated due to the friction between the timing belt and the pulley.

To solve this problem, a method in which the carriage module moves along the rail module in a magnetic levitation manner may be considered. The carriage module may be moved in the vertical direction in a levitated state without contacting the rail module by a linear motor installed in the carriage module or the rail module. In the case of a tower lift in which a carriage module moves along a rail module in a magnetic levitation manner, there is no part that is physically connected to the carriage module, such as a timing belt or rope, in the rail module. Accordingly, when power to drive the tower lift is cut off, the carriage module of the tower lift falls (freely).

### SUMMARY

The inventive concept provides a tower lift and a braking unit capable of stopping a carriage module from falling freely when power driving the tower lift is cut off.

The inventive concept is not limited thereto, and other inventive concepts not mentioned will be clearly understood by those skilled in the art from the description below.

Additional aspects will be set forth in part in the description which follows and, in part, will be apparent from the description, or may be learned by practice of the presented embodiments of the disclosure.

According to an aspect of the inventive concept, there is provided a tower lift including a rail module extending in a vertical direction, a carriage module that is movable in a magnetic levitation manner along the rail module, and a braking device that moves integrally with the carriage module along the rail module, wherein the braking device includes a first braking body configured to prevent the fall of the carriage module through selective contact with the rail module, an elastic member provided above the first braking body and configured to apply an upward elastic force to the first braking body, and an actuator provided below the first braking body and configured to pull the first braking body downward through a rotation shaft connection structure connected to the first braking body.

According to an embodiment, when power is supplied to the actuator, the upward elastic force applied by the elastic member to the first braking body is balanced by the sum of a force by which the actuator pulls the first braking body downward through the rotation shaft connection structure and a weight of the first braking body.

According to an embodiment, when power to the actuator is cut off, the elastic member moves the first braking body in an inclined direction with respect to the vertical direction, which causes the first braking body to contact the rail module.

According to an embodiment, the tower lift further includes a support body that contacts an inclined surface of the first braking body and provides a path for the first braking body.

According to an embodiment, the tower lift further includes a support block provided below the first braking body and protruding toward the rail module, and when power is supplied to the actuator, an upper surface of the support block is in contact with at least a portion of a lower surface of the first braking body to define a lowest vertical level at which the first braking body can operate.

According to an embodiment, the tower lift further includes a second braking body spaced apart from the first braking body and arranged to face the first braking body with the rail module in between, wherein the second braking body selectively contacts the rail module to prevent the fall of the carriage module.

According to an embodiment, the second braking body is connected to the first braking body by a connecting member and is configured to move integrally with the first braking body.

According to an embodiment, when power to the actuator is cut off, the elastic member moves the first braking body in an inclined direction with respect to the vertical direction, which causes the second braking body moving integrally with the first braking body to contact the rail module.

According to an embodiment, the first braking body includes a braking pad disposed on a side of the first braking body facing the rail module and configured to be movable in an inclined direction with respect to the vertical direction.

According to an embodiment, two braking devices are provided, the rotation shaft connection structure is connected to each of the two braking devices, and the actuator drives the two braking devices through the rotation shaft connection structure.

According to another aspect of the inventive concept, there is provided a tower lift including a rail module extending in a vertical direction, a carriage module that is movable in a magnetic levitation manner along the rail module, and a braking device that moves integrally with the carriage module along the rail module, wherein the braking device includes a first braking body configured to prevent the fall of the carriage module through selective contact with the rail module, a first elastic member provided above the first braking body and configured to apply an upward elastic force to the first braking body, a first support body that contacts an inclined surface of the first braking body and provides a path for the first braking body, a second support body spaced apart from the first support body with the rail module positioned therebetween, and an actuator provided below the first braking body and configured to pull the first braking body downward through a rotation shaft connection structure connected to the first braking body.

According to an embodiment, the tower lift further includes a second braking body disposed on a widest side of the second support body, wherein the second braking body is connected to a widest surface of the second support body through a second elastic member having a preset elastic coefficient.

According to an embodiment, the first braking body includes a first braking pad disposed on a side of the first braking body facing the rail module and configured to be movable in an inclined direction with respect to the vertical direction, and the second braking body includes a second braking pad disposed on a side of the second braking body facing the rail module and configured to be movable toward the rail module.

According to an embodiment, when the first braking body brakes the fall of the carriage module, the second support body moves toward the rail module.

According to an embodiment, when power is supplied to the actuator, the upward elastic force applied by the elastic member to the first braking body is balanced by the sum of a force by which the actuator pulls the first braking body downward through the rotation shaft connection structure and a weight of the first braking body.

According to an embodiment, when power to the actuator is cut off, the first elastic member moves the first braking body in an inclined direction with respect to the vertical direction, which causes the first braking body to contact the rail module.

According to an embodiment, when a first braking pad of the first braking body contacts the rail module, the second support body moves toward the rail module, so that a second braking pad of the second braking body contacts the rail module.

According to an embodiment, the tower lift further includes a support block provided below the first braking body and protruding toward the rail module, and when power is supplied to the actuator, an upper surface of the support block is in contact with at least a portion of a lower surface of the first braking body to define a lowest vertical level at which the first braking body can operate.

According to another aspect of the inventive concept, there is provided a tower lift including a rail module extending in a vertical direction, a carriage module that is movable in a magnetic levitation manner along the rail module, and a braking device that moves integrally with the carriage module along the rail module, wherein the braking device includes a first braking body configured to prevent the fall of the carriage module through selective contact with the rail module, an elastic member provided above the first braking body and configured to apply an upward elastic force to the first braking body, a support body that contacts an inclined surface of the first braking body and provides a path for the first braking body, a support block provided below the first braking body and protruding toward the rail module, a second braking body spaced apart from the first braking body and arranged to face the first braking body with the rail module in between, and including a braking pad disposed on a side of the second braking body facing the rail module and configured to be movable in an inclined direction with respect to the vertical direction, a connecting member configured to connect the first braking body to the second braking body so that the first and second braking bodies move integrally, and an actuator provided below the first braking body and configured to pull the first braking body downward through a rotation shaft connected to the first braking body, wherein, when power is supplied to the actuator, an upper surface of the support block is in contact with at least a portion of a lower surface of the first braking body to define a lowest vertical level at which the first braking body can operate.

According to an embodiment, when power is supplied to the actuator, the upward elastic force applied by the elastic member to the first braking body is balanced by a force by which the actuator pulls the first braking body downward through the rotation shaft, and when power to the actuator is cut off, the elastic member moves the first braking body in an inclined direction with respect to the vertical direction, which causes the first braking body to contact the rail module, the elastic member moves the first braking body in an inclined direction with respect to the vertical direction, which causes the second braking body moving integrally with the first braking body to contact the rail module, and the second braking body selectively contacts the rail module to prevent the fall of the carriage module.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram of a semiconductor manufacturing line in which a tower lift is installed according to an embodiment;

FIG. 2 is a perspective view showing a rail module and a carriage module of the tower lift according to an embodiment;

FIG. 3 is a plan cross-sectional view showing the rail module and the carriage module of the tower lift according to an embodiment;

FIG. 4 is a cross-sectional view of a braking device according to an embodiment;

FIGS. 5 and 6 are cross-sectional views showing an operation process of the braking device shown in FIG. 4;

FIG. 7 is a cross-sectional view of a braking device according to an embodiment;

FIGS. 8 and 9 are cross-sectional views showing an operation process of the braking device shown in FIG. 7; and

FIGS. 10 and 11 are a plan view and a cross-sectional view of a tower lift according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments are described in detail with reference to the accompanying drawings. However, the disclosure does not have to be configured as limited to the embodiments described below and may be embodied in various other forms. The following embodiments are not provided to fully complete the disclosure, but rather are provided to fully convey the scope of the disclosure to those skilled in the art.

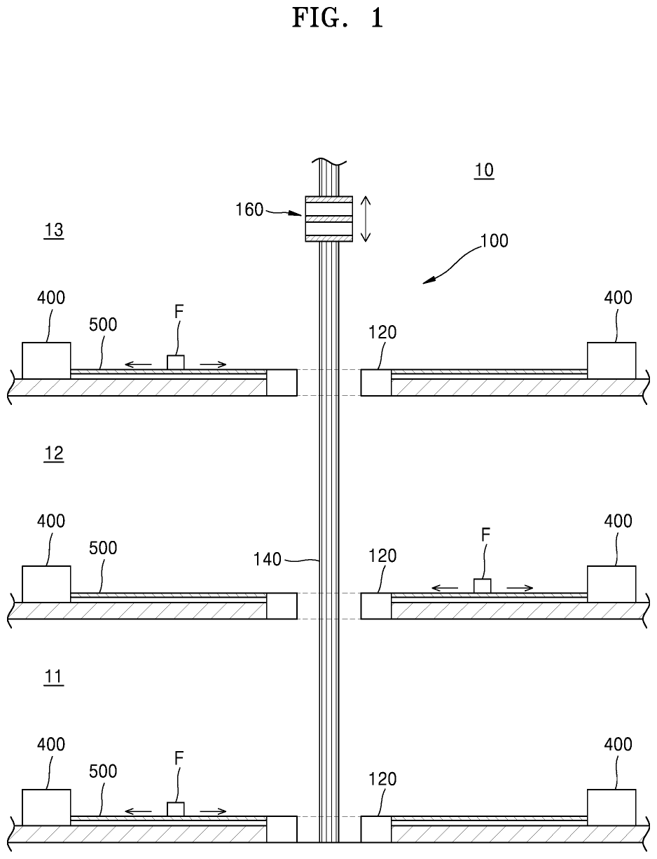

FIG. 1 is a schematic diagram of a semiconductor manufacturing line in which a tower lift is installed according to an embodiment. Referring to FIG. 1, a semiconductor manufacturing line 10 may include multiple floors. For example, the semiconductor manufacturing line 10 may include a first floor 11, a second floor 12, and a third floor 13. However, the disclosure is not limited thereto, and the multi-floor structure of the semiconductor manufacturing line 10 may be modified in various ways.

The semiconductor manufacturing line 10 may include a tower lift 100, a container storage unit 400, a transport rail 500, and semiconductor manufacturing devices (not shown) that perform a semiconductor manufacturing process.

The tower lift 100 (an example of a magnetically levitated vertical drive module) transports a container F containing articles between each floor 11, 12, and 13 of the semiconductor manufacturing line 10. The tower lift 100 may include stage modules 120, a rail module 140, and a carriage module 160.

The stage module 120 may be installed on the bottom of each floor 11, 12, and 13 of the semiconductor manufacturing line 10. The stage module 120 may be combined with a transport rail 500 that transports the container F to the container storage unit 400. When the tower lift 100 transports the container F to each floor 11, 12, and 13, the container F transported to each floor 11, 12, and 13 may be transported to the container storage unit 400 by the transport rail 500.

The rail module 140 may extend in a vertical direction. The rail module 140 may extend in the vertical direction between at least two floors of the semiconductor manufacturing line 10. The rail module 140 may guide the movement of the carriage module 160, which is described below. Additionally, the rail module 140 may move the carriage module 160, which is described below, in the vertical direction.

The carriage module 160 (an example of a moving body) may be configured to be movable along the rail module 140. For example, the carriage module 160 may be configured to be movable in the vertical direction along the rail module 140. The carriage module 160 may have a carriage 162 that transports articles. A plurality of carriage modules 160 may be provided. For example, the number of carriage modules 160 may vary.

The carriage module 160 may have a seating shelf on which the container F containing articles is placed. Alternatively, the carriage module 160 may have a robot that grips the container F. The carriage module 160 may be modified into various structures capable of moving the container F.

Hereinafter, the rail module 140 and the carriage module 160 according to an embodiment are described in detail.

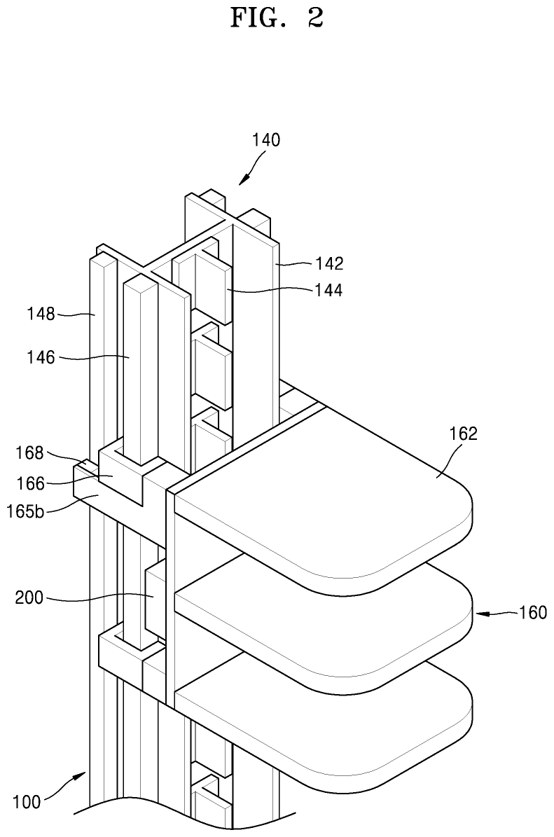

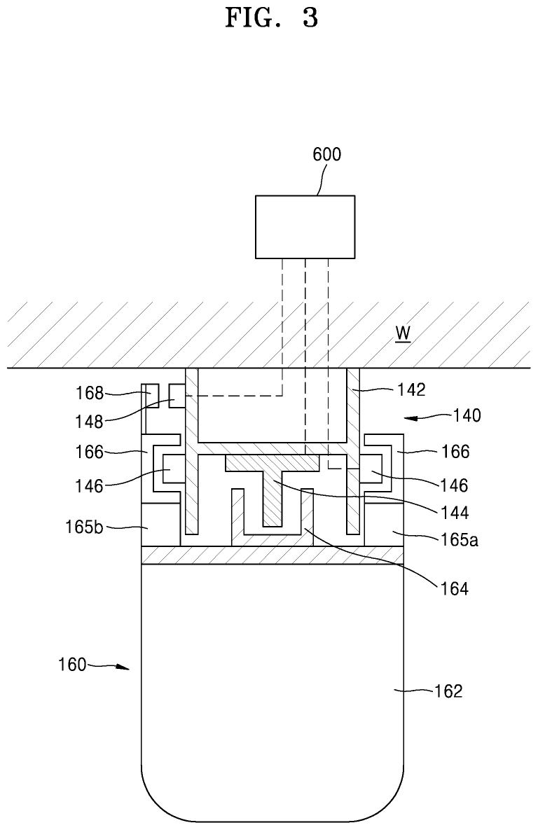

FIG. 2 is a perspective view showing a rail module and a carriage module of a tower lift according to an embodiment. FIG. 3 is a plan cross-sectional view showing a rail module and a carriage module of a tower lift according to an embodiment.

Referring to FIGS. 2 and 3, the rail module 140 may include a frame 142, a linear motor coil 144, a guide rail 146, and a power transmitter 148.

The frame 142 may extend in the vertical direction. A longitudinal direction of the frame 142 may be the vertical direction. The frame 142 may be fixedly installed on a wall W of the semiconductor manufacturing line 10. The linear motor coil 144, the guide rail 146, and the power transmitter 148, which are described below, may be coupled to the frame 142. The frame 142 may have an overall “H” shape when viewed from the top, but is not limited thereto, and the shape of the frame 142 may be modified in various ways.

The linear motor coil 144 may move the carriage 162 in the vertical direction through interaction with a linear motor magnet 164, which is described below. The interaction may be caused by magnetic force generated by the linear motor coil 144 and/or the linear motor magnet 164. The linear motor coil 144 may be installed on the frame 142. The linear motor coil 144 may be installed on a side of the frame 142 opposite the carriage module 160 when viewed from the top. The linear motor coil 144 may generally have a “ [symbol] ” shape.

Additionally, interface lines (not shown) such as power lines may be connected to the linear motor coil 144. Additionally, a plurality of pairs of linear motor coils 144 may be provided. The plurality of pairs of linear motor coils 144 may be installed on the frame 142 while being spaced apart from each other in the vertical direction in which the frame 142 extends.

The guide rail 146 may constrain some of the degrees of freedom of the carriage module 160. The guide rail 146 may constrain the remaining degrees of freedom thereof except for the degrees of freedom of vertical movement of the carriage module 160. The guide rail 146 may be spaced apart from a guide unit 166 of the carriage module 160, which is described below, by repulsive force due to magnetic force. The interface lines (not shown) such as power lines may be connected to the guide rail 146. In addition, a gap sensor (not shown) is provided on either the guide rail 146 or the guide unit 166, and the magnetic force may be controlled based on a measurement value measured by the gap sensor. Accordingly, the gap between the guide rail 146 and the guide unit 166 may be controlled to be substantially constant.

At least one guide rail 146 may be provided. For example, a plurality of guide rails 146 may be provided. One of the guide rails 146 may be installed on one side of the frame 142, and the other one of the guide rails 146 may be installed on the other side of the frame 142. For example, one of the guide rails 146 may be installed on one sidewall of the frame 142, and the other one of the guide rails 146 may be installed on the other sidewall of the frame 142. Additionally, a longitudinal direction of the guide rail 146 may be the same as the longitudinal direction of the frame 142.

The power transmitter 148 may transmit power to a power receiver 168 of the carriage module 160, which is described below. For example, the power transmitter 148 may be one of non-contact power supply (HID) configurations that supply power in a non-contact manner. The power transmitter 148 may be installed on the frame 142. The power transmitter 148 may be installed on any one of sides of the frame 142 where the guide rail 146 is installed. For example, the power transmitter 148 may be installed on one sidewall of the frame 142 where the guide rail 146 is installed. The interface lines (not shown) such as power lines may be connected to the power transmitter 148.

The carriage module 160 may transport the container F containing articles. The carriage module 160 may be configured to be movable in the vertical direction along the rail module 140. The carriage module 160 may move in the vertical direction along the rail module 140 to transport the container F containing articles to each floor 11, 12, and 13 of the semiconductor manufacturing line 10. The carriage module 160 may include the carriage 162, the linear motor magnet 164, connection bodies 165a and 165b, the guide unit 166, and the power receiver 168.

The carriage 162 may have a shape of the seating shelf on which the container F containing articles may be seated. The carriage 162 may be provided with a robot (not shown) that grips the container F containing articles. In FIG. 2, the carriage 162 is shown in the shape of a three-stage shelf, but is not limited thereto, and the shape of the carriage 162 may be modified in various ways.

The linear motor magnet 164 may be coupled to the carriage 162. The linear motor magnet 164 may move the carriage 162 in the vertical direction through interaction with the linear motor coil 144 described above. The interaction may be caused by magnetic force generated by the linear motor coil 144 and/or the linear motor magnet 164.

Additionally, the linear motor magnet 164 may have an overall “ [symbol] ” shape when viewed from the top. Accordingly, a portion of the linear motor coil 144 may be fitted into an open portion of the linear motor magnet 164.

The connection bodies 165a and 165b may couple the guide unit 166 and the power receiver 168, which are described below, to the carriage 162. The connection bodies 165a and 165b may include a first connection body 165a and a second connection body 165b. The first connection body 165a and the second connection body 165b may have different shapes. The second connection body 165b may couple the guide unit 166 and the power receiver 168 to the carriage 162. The first connection body 165a may couple the guide unit 166 to the carriage 162.

The guide unit 166 may be coupled to the carriage 162 by the connection bodies 165a and 165b. Accordingly, when the carriage 162 moves, the guide unit 166 may move in the vertical direction together with the carriage 162. The guide unit 166 may have a shape that surrounds at least a portion of the guide rail 146 installed on the frame 142. The guide unit 166 may have a “ [symbol] ” shape when viewed from the top. The guide rail 146 may be fitted into the guide unit 166. Accordingly, except for the degrees of freedom of the vertical movement of the carriage module 160, the guide unit 166, together with the guide rail 146, may constrain the remaining degrees of freedom thereof. In addition, the gap sensor (not shown) may be provided on either the guide rail 146 or the guide unit 166, and the magnetic force may be controlled based on the measurement value measured by the gap sensor. Accordingly, the gap between the guide rail 146 and the guide unit 166 may be controlled to be substantially constant.

The power receiver 168 may receive power transmitted from the power transmitter 148. Additionally, the power receiver 168 may be installed opposite to the power transmitter 148. The power receiver 168 may be one of HID configurations that supply power in a non-contact manner. The power receiver 168 may be coupled to the carriage 162 via the second connection body 165b. Accordingly, when the carriage 162 moves, the power receiver 168 may move in the vertical direction together with the carriage 162.

The carriage module 160 according to an embodiment includes the linear motor magnet 164, and the linear motor magnet 164 may move the carriage 162 along the rail module 140 through interaction with the linear motor coil 144. That is, the carriage module 160 according to an embodiment may move along the rail module 140 in a magnetic levitation manner. In a typical tower lift, a carriage module is moved by friction between a timing belt and a pulley, where particles may be generated. However, the carriage module 160 according to an embodiment may move along the rail module 140 in a magnetic levitation manner, thereby minimizing particle generation.

Additionally, the carriage module 160 may include the power receiver 168 and may receive power from the power transmitter 148 in a non-contact manner. That is, the power required to drive the carriage module 160 may be received in a non-contact manner. In addition, in the disclosure, the linear motor coil 144 that requires connection to power lines may be installed in the frame 142, and the carriage module 160 may include the linear motor magnet 164 that does not require connection to power lines. That is, all interface lines, such as power lines, are connected to components of the rail module 140, and no interface lines may be connected to the carriage module 160. When the interface lines are connected to the carriage module 160, the interface lines interfere with the operation of a plurality of carriage modules 160, but no interface lines are connected to the carriage module 160 according to an embodiment, which enables the easier operation of the plurality of carriage modules 160.

Additionally, a plurality of pairs of linear motor coils 144 included in the rail module 140 may be provided and installed on the frame 142 while being spaced apart from each other in the longitudinal direction of the frame 142.

A controller 600 may control the tower lift 100. The controller 600 may control the tower lift 100 so that the carriage module 160 moves along the rail module 140 in a magnetic levitation manner. In addition, the controller 600 may include a process controller consisting of a microprocessor (computer) that controls the tower lift 100, a user interface consisting of a keyboard that allows an operator to input commands to manage the tower lift 100 and a display that visualizes and displays the operation status of the tower lift 100, and memory where processing recipes are stored, i.e., a control program for executing processing performed in the tower lift 100 under the control of the process controller, or a program for executing processing in each component according to various data and processing conditions. Additionally, the user interface and the memory may be connected to the process controller. The processing recipes may be stored in a storage medium in the storage unit, and the storage medium may be a hard disk, a portable disk, such as a CD-ROM or DVD, or semiconductor memory such as flash memory.

As such, the carriage module 160 according to an embodiment may be moved along the rail module 140 in a magnetic levitation method. Accordingly, when the power driving the carriage module 160 is cut off, the carriage module 160 may fall (free fall). Accordingly, a first braking unit 200 may be installed in the carriage module 160 of the tower lift 100 according to an embodiment. When the power driving the tower lift 100 is cut off, the carriage module 160 may fall, and the first braking unit 200 may prevent the fall of the carriage module 160 even when the power is cut off.

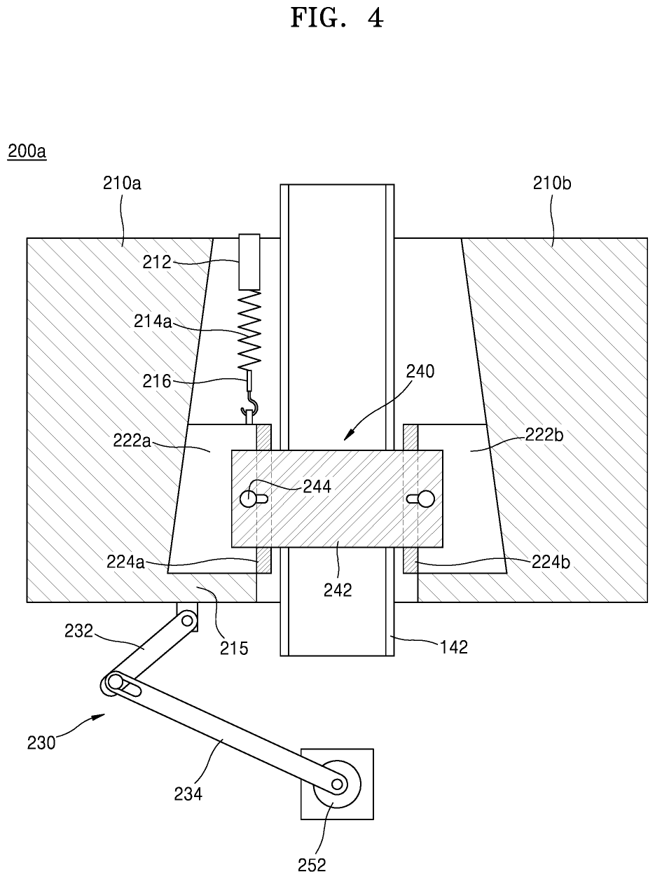

FIG. 4 is a cross-sectional view of a braking device 200a according to an embodiment.

Referring to FIG. 4 along with FIG. 2, the tower lift 100 may include the rail module 140 extending in the vertical direction. The rail module 140 may include the frame 142 extending in the vertical direction. The frame 142 may have an overall “H” shape when viewed from the top. Additionally, the tower lift 100 may include the carriage module 160 that is movable in a magnetic levitation manner along the rail module 140.

According to an embodiment, the tower lift 100 includes a braking device 200a that moves integrally with the carriage module 160 along the rail module 140. The braking device 200a may include a first braking body 222a that selectively contacts the rail module 140 to prevent the fall of the carriage module 160. The first braking body 222a may have a trapezoidal shape in which one side of the first braking body 22a is inclined, and the other side opposite to the one side thereof is flat in the vertical direction.

The tower lift 100 may further include a support body 210a that contacts an inclined surface of the first braking body 222a and provides a path for the first braking body 222a. The support body 210a may include an inclined side, and the inclined side of the support body 210a may be in contact with the first braking body 222a. The first braking body 222a may include a braking pad 224a disposed on a side of the first braking body 222a facing the rail module 140 and configured to be movable in an inclined direction with respect to the vertical direction. The braking pad 224a may include a material having a preset coefficient of friction. A widest surface of the braking pad 224a may be configured to contact at least a portion of the frame 142 of the rail module 140 and prevent the fall of the carriage module 160.

According to an embodiment, the braking device 200a may include an elastic member 214a provided above the first braking body 222a and configured to apply an upward elastic force to the first braking body 222a. The elastic member 214a may be a spring having a preset elastic coefficient, but is not necessarily limited thereto. One side of the elastic member 214a may be connected to a fixing member 212 fixed to one end of the carriage module 160.

According to an embodiment, the braking device 200a may include an actuator 252 configured to pull the first braking body 222a downward through a rotation shaft connection structure 230 provided below the first braking body 222a and connected to the first braking body 222a. The rotation shaft connection structure 230 may include a first rotation shaft 232 connected to the first braking body 222a, and a second rotation shaft 234 connecting the first rotation shaft 232 to the actuator 252.

According to an embodiment, when power is supplied to the actuator 252, the braking device 200a may be defined as not functioning. The upward elastic force applied by the elastic member 214 to the first braking body 222a may be balanced by the sum of the force by which the actuator 252 pulls the first braking body 222a downward through the rotary shaft connection structure 230 and the weight of the first braking body 222a.

The braking device 200a may further include a support block 215 provided below the first braking body 222a and protruding toward the rail module 140. When power is supplied to the actuator 252, an upper surface of the support block 215 may be in contact with at least a portion of a lower surface of the first braking body 222a to define a lowest vertical level at which the first braking body 222a can operate.

In addition, the braking device 200a may further include a second braking body 222b spaced apart from the first braking body 222a and arranged to face the first braking body 222a with the rail module 140 in between. The second braking body 222b may also selectively contact the rail module 140 to prevent the fall of the carriage module 160. The second braking body 222b may be connected to the first braking body 222a and may be configured to move integrally with the first braking body 222a. Accordingly, the second braking body 222b depends on the movement of the first braking body 222a.

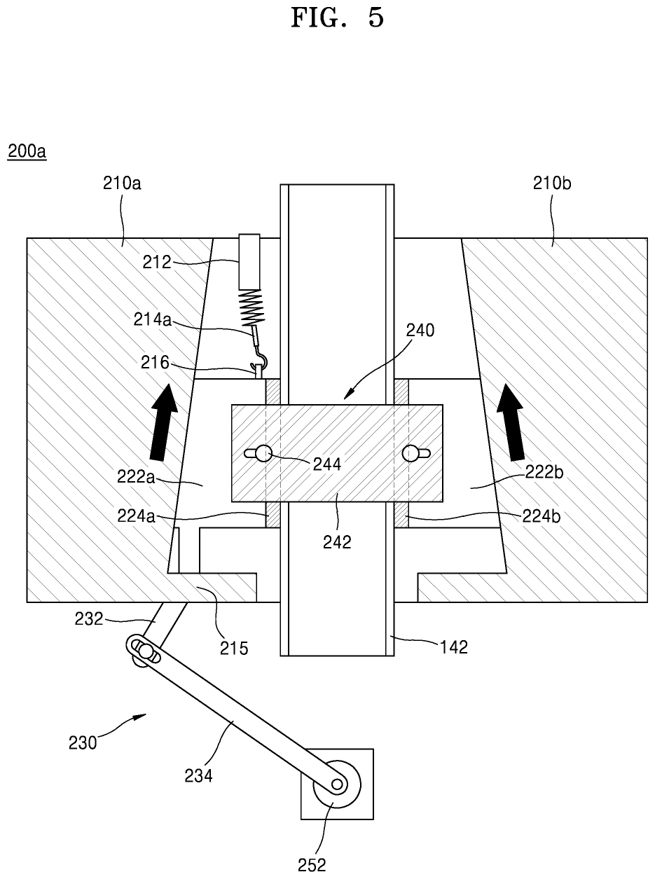

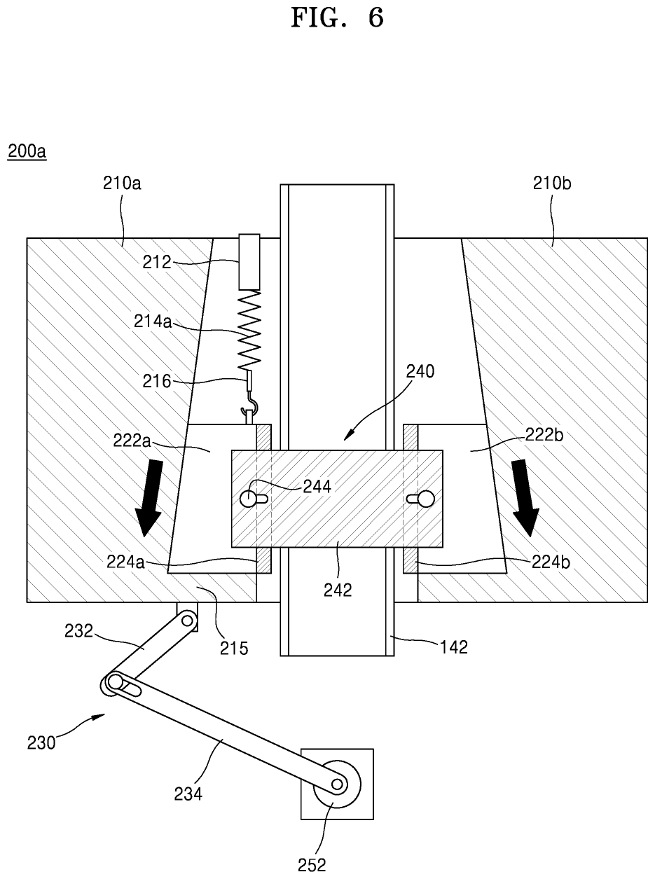

FIGS. 5 and 6 are cross-sectional views showing the operation process of the braking device shown in FIG. 4. Specifically, FIG. 5 is a cross-sectional view showing a case where the braking device 200a operates when power to the actuator 252 is cut off. In addition, FIG. 6 is a cross-sectional view showing a case where the braking device 200a returns to its original state when power is supplied to the actuator 252 again.

Referring to FIG. 5, when power to the actuator 252 is cut off, the elastic member 214a may allow the first braking body 222a to contact the rail module 140 by moving the first braking body 222a in an inclined direction with respect to the vertical direction. In addition, since the second braking body 222b moves integrally with the first braking body 222a through a connecting member 240, when power to the actuator 252 is cut off, the elastic member 214a may allow the second braking body 222b to contact the rail module 140 by moving the first braking body 222a in an inclined direction with respect to the vertical direction.

Referring to FIG. 6, when power is supplied to the actuator 252 again, the actuator 252 may pull the first braking body 222a downward through the rotation shaft connection structure 230. As the first braking body 222a is pulled downward, a first braking pad 224a of the first braking body 222a and a second braking pad 224b of the second braking body 222b are spaced apart from the frame 142 of the rail module 140.

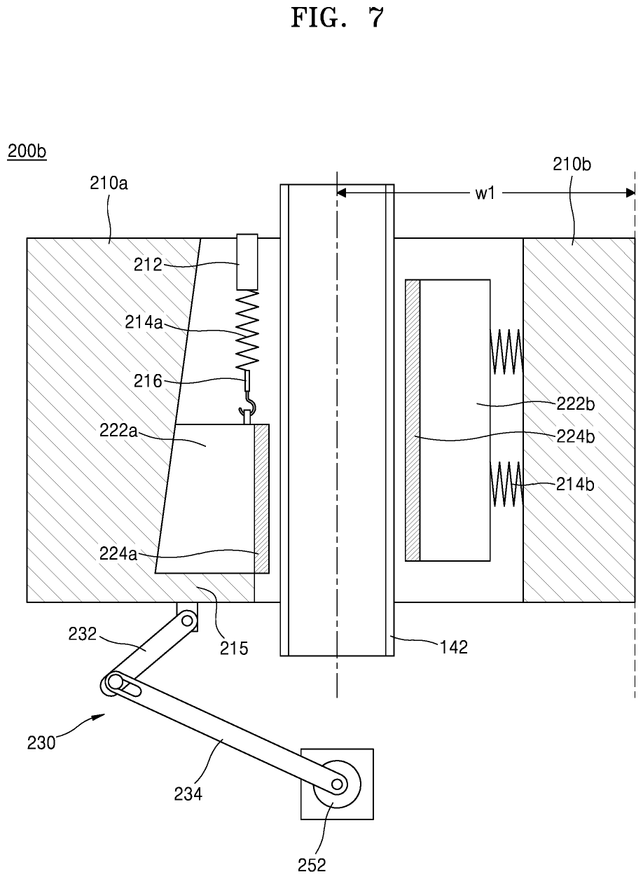

FIG. 7 is a cross-sectional view of a braking device 200b according to an embodiment. The braking device 200b shown in FIG. 7 is similar to the braking device 200a shown in FIG. 4 except that a second support body 210b has a flat cross-section with no inclination, and that when the first braking body 222a contacts the frame 142 of the rail module 140, the second support body 210b moves toward the rail module 140. Therefore, the description of the components described with reference to FIGS. 4 to 6 is simplified or omitted.

Referring to FIG. 7 along with FIG. 2, the tower lift 100 may include the rail module 140 extending in the vertical direction. The rail module 140 may include the frame 142 extending in the vertical direction. Additionally, the tower lift 100 may include the carriage module 160 that is movable in a magnetic levitation manner along the rail module 140. The rail module 140 and carriage module 160 shown in FIG. 7 are the same as those shown in FIG. 4.

According to an embodiment, the tower lift 100 includes the braking device 200b that moves integrally with the carriage module 160 along the rail module 140. The braking device 200b may include a first braking body 222a that selectively contacts the rail module 140 to prevent the fall of the carriage module 160. The first braking body 222a shown in FIG. 7 is the same as that shown in FIG. 4.

The tower lift 100 may further include a first support body 210a that contacts an inclined surface of the first braking body 222a and provides a path for the first braking body 222a. The first braking body 222a may include a first braking pad 224a disposed on a surface of the first braking body 222a facing the rail module 140 and configured to be movable in an inclined direction with respect to the vertical direction. The first support body 210a and the first braking pad 224a shown in FIG. 7 are the same as the support body 210a and the braking pad 224a shown in FIG. 4.

According to an embodiment, the braking device 200b may include an elastic member 214a provided above the first braking body 222a and configured to apply an upward elastic force to the first braking body 222a. The elastic member 214a shown in FIG. 7 is the same as that shown in FIG. 4.

According to an embodiment, the braking device 200b may include an actuator 252 configured to pull the first braking body 222a downward through a rotation shaft connection structure 230 provided below the first braking body 222a and connected to the first braking body 222a. The rotation shaft connection structure 230 shown in FIG. 7 is the same as that shown in FIG. 4.

According to an embodiment, when power is supplied to the actuator 252, the braking device 200b may be defined as not functioning. The upward elastic force applied by the elastic member 214a to the first braking body 222a may be balanced by the sum of a force by which the actuator 252 pulls the first braking body 222a downward through the rotary shaft connection structure 230 and a weight of the first braking body 222a.

The braking device 200b may further include a support block 215 provided below the first braking body 222a and protruding toward the rail module 140. When power is supplied to the actuator 252, an upper surface of the support block 215 may be in contact with at least a portion of a lower surface of the first braking body 222a to define a lowest vertical level at which the first braking body 222a can operate.

In addition, the braking device 200b may further include a second breaking body 222b spaced apart from the first braking body 222a and arranged to face the first braking body 222a with the rail module 140 in between. Unlike the first support body 210a, the second support body 210b may have a flat widest surface with no inclination. The second braking body 222b may further include a second elastic member 214b disposed on the widest surface of the second support body 210b. The second braking body 222b may be connected to the widest surface of the second support body 210b through the second elastic member 214b having a preset elastic coefficient.

According to an embodiment, the first braking body 222a includes the first braking pad 224a disposed on a surface of the first braking body 222a facing the rail module 140 and configured to be movable in an inclined direction with respect to the vertical direction. On the other hand, the second braking pad 224b of the second braking body 222b may be configured to be movable toward the rail module 140 and may be disposed on a surface of the second braking body 222b facing the rail module 140.

FIG. 7 shows a case where power is supplied to the actuator 252 and the braking device 200b is not operating. In this case, the upward elastic force applied by the elastic member 214a to the first braking body 222a may be balanced by the sum of a force by which the actuator 252 pulls the first braking body 222a downward through the rotary shaft connection structure 230 and a weight of the first braking body 222a. Accordingly, the first braking body 222a does not move upward.

According to an embodiment, the braking device 200b further includes the support block 215 provided below the first braking body 222a and protruding toward the rail module 140. When power is supplied to the actuator 252, an upper surface of the support block 215 may be in contact with at least a portion of a lower surface of the first braking body 222a to define a lowest vertical level at which the first braking body 222a can operate.

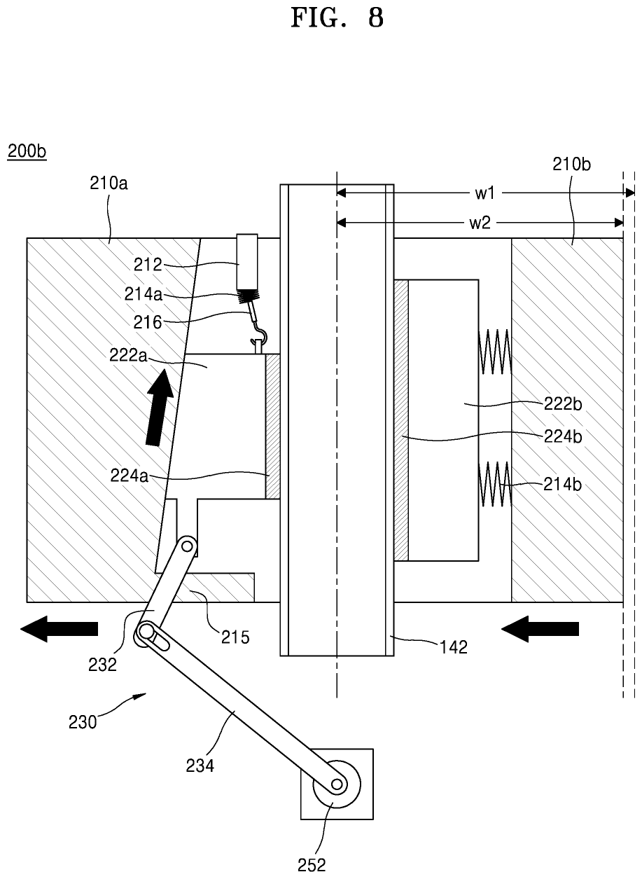

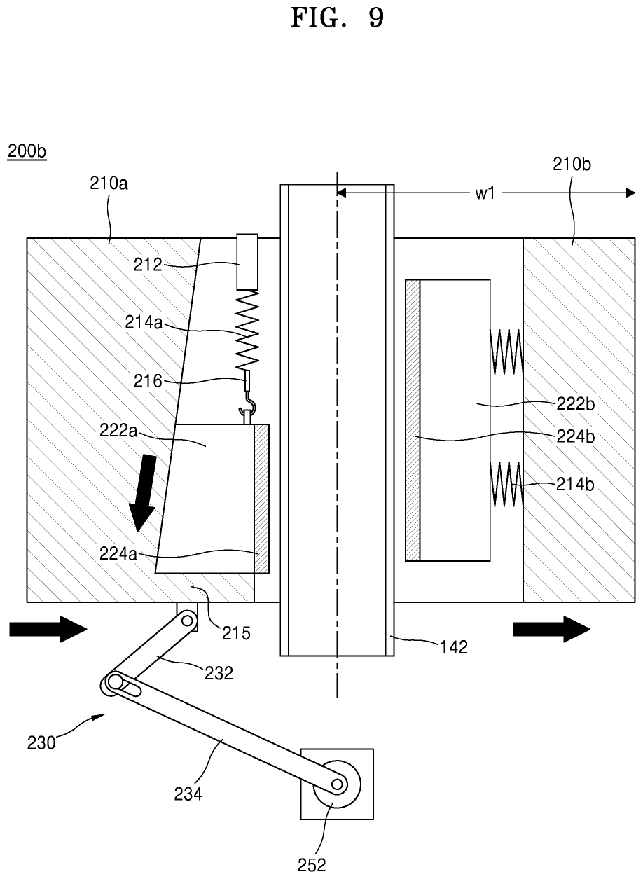

FIGS. 8 and 9 are cross-sectional views showing the operation process of the braking device 200b shown in FIG. 7. Specifically, FIG. 8 is a cross-sectional view showing a case where power to the actuator 252 is cut off and the braking device 200b is not operating. FIG. 9 is a cross-sectional view showing a case where the braking device 200b returns to its original state when power is supplied to the actuator 252 again.

Referring to FIG. 8, when power to the actuator 252 is cut off, a first elastic member 214a may allow the first braking body 222a to contact the rail module 140 by moving the first braking body 222a in an inclined direction with respect to the vertical direction. Specifically, the first braking pad 224a of the first braking body 222a is brought into contact with the frame 142 of the rail module 140. When power to the actuator 252 is cut off, the force by which the actuator 252 pulls the first braking body 222a downward through the rotation shaft connection structure 230 disappears. Accordingly, along the inclined surface of the first support body 210a, the first braking body 222a may move in a direction inclined with respect to the vertical direction.

According to an embodiment, when the first braking body 222a moves in an inclined direction with respect to the vertical direction to prevent the fall of the carriage module 160, the second support body 210b moves toward the rail module 140. Specifically, before the first braking body 222a moves, the distance between the central axis of the rail module 140 and a side of the second support body 210b furthest from the central axis thereof may be a first distance w1. When the first braking body 222a brakes the fall of the carriage module 160 and the second support body 210b moves toward the rail module 140, the distance between the central axis of the rail module 140 and the side of the second support body 210b furthest from the central axis thereof may be a second distance w2.

According to an embodiment, when the first braking pad 224a of the first braking body 222a contacts the frame 142 of the rail module 140, the second support body 210b moves toward the rail module 140. The second braking pad 224b of the second braking body 222b may contact the frame 142 of the rail module 140.

Referring to FIG. 9, when power is supplied to the actuator 252 again, the actuator 252 may pull the first braking body 222a downward through the rotation shaft connection structure 230. As the first braking body 222a is pulled downward, the first braking pad 224a of the first braking body 222a and the second braking pad 224b of the second braking body 222b may be spaced apart from the frame 142 of the rail module 140.

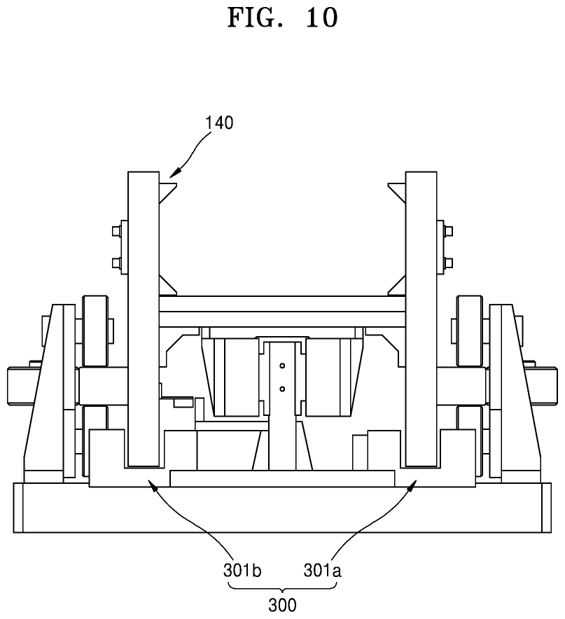

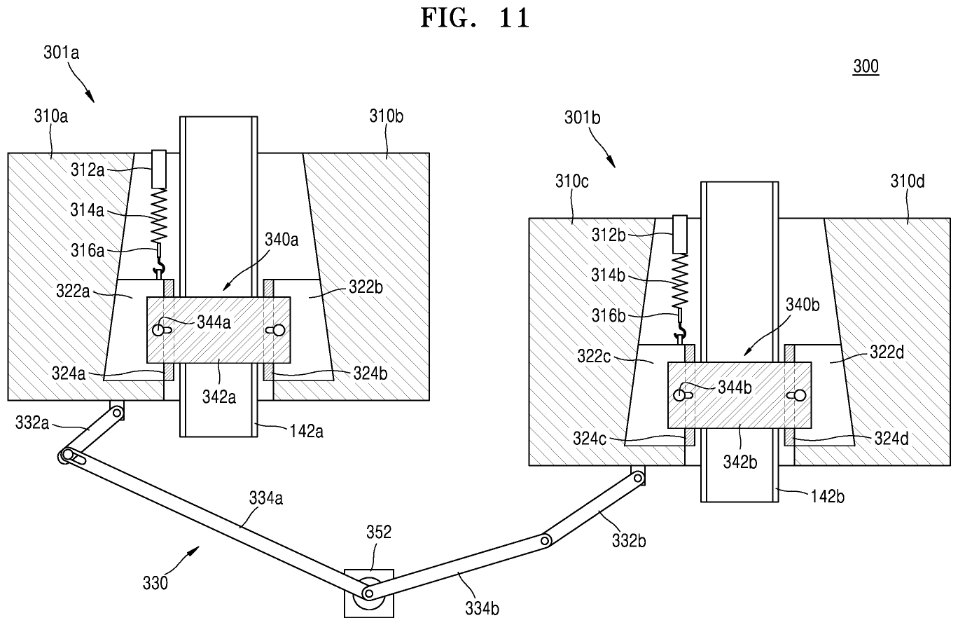

FIGS. 10 and 11 are a plan view and a cross-sectional view of a tower lift according to an embodiment.

Referring to FIGS. 10 and 11, the tower lift may include a pair of rail modules 140 and a braking device 300 surrounding each of the rail modules 140. According to an embodiment, the pair of rail modules 140 extending in the vertical direction may be spaced apart from each other in a horizontal direction.

The braking device 300 may include a first braking device 301a and a second braking device 301b horizontally spaced apart from the first braking device 301a. The first braking device 301a and the second braking device 301b shown in FIGS. 10 and 11 may be substantially the same as the braking device 200a shown in FIGS. 4 to 6. Hereinafter, description of the same components as those of the braking device 200a shown in FIGS. 4 to 6 is omitted or simplified.

Unlike the braking device 200a shown in FIGS. 4 to 6, one rotation shaft connection structure 330 shown in FIGS. 10 and 11 may be connected to both the first braking device 301a and the second braking device 301b. The rotation shaft connection structure 330 may include a first rotation shaft 332a connected to the first braking body 322a of the first braking device 301a and a second rotation shaft 334a. In addition, the rotation shaft connection structure 330 may include a third rotation shaft 332b connected to a third braking body 322c of the second braking device 301b, and a fourth rotation shaft 334b. The second rotation shaft 334a and the fourth rotation shaft 334b may be one shaft. When the second rotation shaft 334a and the fourth rotation shaft 334b are one shaft, one end of the shaft may be connected to the first rotation shaft 332a and the other end of the shaft may be connected to the third rotation shaft 332b. The shaft may be connected to the actuator 352 at a location between one end and the other end of the shaft.

The braking device 300 shown in FIGS. 10 and 11 may be substantially the same as that of the braking device 200a shown in FIGS. 4 to 6. However, when power to the actuator 352 connected to the one rotation shaft connection structure 330 is cut off, the first braking device 301a and the second braking device 301b may operate simultaneously. Accordingly, the plurality of braking bodies 322a, 322b, 322c, and 322d of the first braking device 301a and the second braking device 301b may each contact a plurality of rail modules 140 to prevent the fall of the carriage module.

The braking device 300 shown in FIGS. 10 and 11 may be substantially the same as the braking device 200b shown in FIGS. 7 to 9. Specifically, two braking devices 200b as shown in FIGS. 7 to 9 are provided, and the two braking devices 200b may operate with one rotation shaft connection structure 330.

That is, two braking devices according to some embodiments are provided, and the two braking devices may operate with one rotation shaft connection structure, or one braking device according to some embodiments is provided, and the one braking device may operate with one rotation shaft connection structure. The number of braking devices and the number of rotation shaft connection structures are not limited, and modifications to various numbers are possible.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A tower lift comprising:
a rail module extending in a vertical direction;
a carriage module that is movable in a magnetic levitation manner along the rail module; and
a braking device configured to move integrally with the carriage module along the rail module,
wherein the braking device comprises:
a first braking body configured to prevent the carriage module from falling through selective contact with the rail module;
an elastic member provided above the first braking body and configured to apply an upward elastic force to the first braking body; and
an actuator provided below the first braking body and configured to pull the first braking body downward through a rotation shaft connection structure connected to the first braking body.

2. The tower lift of claim 1,
wherein, when power is supplied to the actuator,
the upward elastic force applied by the elastic member to the first braking body is balanced by a sum of a force by which the actuator pulls the first braking body downward through the rotation shaft connection structure and a weight of the first braking body.

3. The tower lift of claim 1,
wherein, when power to the actuator is cut off,
the elastic member is configured to move the first braking body in an inclined direction with respect to the vertical direction to cause the first braking body to contact the rail module.

4. The tower lift of claim 1,
further comprising a support body that contacts an inclined surface of the first braking body and provides a path for the first braking body.

5. The tower lift of claim 1,
further comprising a support block provided below the first braking body and protruding toward the rail module,
wherein, when power is supplied to the actuator, an upper surface of the support block is in contact with at least a portion of a lower surface of the first braking body to define a lowest vertical level at which the first braking body can operate.

6. The tower lift of claim 1,
further comprising a second braking body spaced apart from the first braking body and arranged to face the first braking body with the rail module in between,
wherein the second braking body selectively contacts the rail module to prevent the carriage module from falling.

7. The tower lift of claim 6,
wherein the second braking body is
connected to the first braking body by a connecting member and is configured to move integrally with the first braking body.

8. The tower lift of claim 6,
wherein, when power to the actuator is cut off,
the elastic member is configured to move the first braking body in an inclined direction with respect to the vertical direction to cause the second braking body to move integrally with the first braking body to contact the rail module.

9. The tower lift of claim 1,
wherein the first braking body
comprises a braking pad configured to be movable in an inclined direction with respect to the vertical direction, and
disposed on a side of the first braking body facing the rail module.

10. The tower lift of claim 1,
wherein two braking devices are provided,
the rotation shaft connection structure is connected to each of the two braking devices, and
the actuator is configured to drive the two braking devices through the rotation shaft connection structure.

11. A tower lift comprising:
a rail module extending in a vertical direction;
a carriage module that is movable in a magnetic levitation manner along the rail module; and
a braking device configured to move integrally with the carriage module along the rail module,
wherein the braking device comprises:
a first braking body configured to prevent the carriage module from falling through selective contact with the rail module;
a first elastic member provided above the first braking body and configured to apply an upward elastic force to the first braking body;
a first support body that contacts an inclined surface of the first braking body and provides a path for the first braking body;
a second support body spaced apart from the first support body with the rail module positioned therebetween; and
an actuator provided below the first braking body and configured to pull the first braking body downward through a rotation shaft connection structure connected to the first braking body.

12. The tower lift of claim 11,
further comprising a second braking body disposed on a widest side of the second support body,
wherein the second braking body is connected to a widest surface of the second support body through a second elastic member having a preset elastic coefficient.

13. The tower lift of claim 12,
wherein, when power to the actuator is cut off,
the first elastic member is configured to move the first braking body in an inclined direction with respect to the vertical direction to cause the first braking body to contact the rail module.

14. The tower lift of claim 13,
wherein, when a first braking pad of the first braking body contacts the rail module, the second support body moves toward the rail module so that a second braking pad of the second braking body contacts the rail module.

15. The tower lift of claim 12,
wherein the first braking body
comprises a first braking pad configured to be movable in an inclined direction with respect to the vertical direction, and
disposed on a side of the first braking body facing the rail module,
wherein the second braking body
comprises a second braking pad configured to be movable toward the rail module and
disposed on a side of the second braking body facing the rail module.

16. The tower lift of claim 11,
wherein, when the first braking body stops the carriage module from falling, the second support body moves toward the rail module.

17. The tower lift of claim 11,
wherein, when power is supplied to the actuator,
the upward elastic force applied by the elastic member to the first braking body is balanced by a sum of a force by which the actuator pulls the first braking body downward through the rotation shaft connection structure and a weight of the first braking body.

18. The tower lift of claim 11,
wherein two braking devices are provided,
the rotation shaft connection structure is connected to each of the two braking devices, and
the actuator drives the two braking devices through the rotation shaft connection structure.

19. A tower lift comprising:
a rail module extending in a vertical direction;
a carriage module that is movable in a magnetic levitation manner along the rail module; and
a braking device configured to move integrally with the carriage module along the rail module,
wherein the braking device comprises:
a first braking body configured to prevent the carriage module from falling through selective contact with the rail module;
an elastic member provided above the first braking body and configured to apply an upward elastic force to the first braking body;
a support body that contacts an inclined surface of the first braking body and provides a path for the first braking body;
a support block provided below the first braking body and protruding toward the rail module;
a second braking body spaced apart from the first braking body and arranged to face the first braking body with the rail module in between, and comprising a braking pad disposed on a side of the second braking body facing the rail module and configured to be movable in an inclined direction with respect to the vertical direction;
a connecting member configured to connect the first braking body to the second braking body so that the first and second braking bodies move integrally with each other; and
an actuator provided below the first braking body and configured to pull the first braking body downward through a rotation shaft connected to the first braking body,
wherein two braking devices are provided, the rotation shaft is connected to each of first braking bodies of the two braking devices, and the actuator is configured to drive the two braking devices,
wherein, when power is supplied to the actuator, an upper surface of the support block is in contact with at least a portion of a lower surface of the first braking body to define a lowest vertical level at which the first braking body can operate.

20. The tower lift of claim 19,
wherein, when power is supplied to the actuator,
the upward elastic force applied by the elastic member to the first braking body is balanced by a force by which the actuator pulls the first braking body downward through the rotation shaft,
wherein, when power to the actuator is cut off,
the elastic member moves the first braking body in an inclined direction with respect to the vertical direction to cause the first braking body to contact the rail module,
the elastic member moves the first braking body in an inclined direction with respect to the vertical direction to cause the second braking body to move integrally with the first braking body to contact the rail module, and
the second braking body is configured to
selectively contact the rail module to prevent the carriage module from falling.
